(19) United States
(12) Patent Application Publication
(10) Pub. No.: US 2026/0094639 A1
(43) Pub. Date: Apr. 2, 2026

(54) MEMORY DEVICE AND DRIVING METHOD OF SENSING DEVICE INCLUDED IN MEMORY DEVICE

(71) Applicant: Samsung Electronics Co., Ltd., Suwon-si (KR)

(72) Inventors: Chang Young LEE, Suwon-si (KR); Young Seok PARK, Suwon-si (KR); Hyun-Chul YOON, Suwon-si (KR); Keon Woo PARK, Suwon-si (KR); Young Hun SEO, Suwon-si (KR); Dong Hak SHIN, Suwon-si (KR)

(21) Appl. No.: 19/322,173

(22) Filed: Sep. 8, 2025

(30) Foreign Application Priority Data
Sep. 27, 2024 (KR) 10-2024-0131672

(51) Int. Cl. G11C 11/4091; G11C 11/4074; G11C 11/4094

(52) U.S. Cl. CPC G11C 11/4091; G11C 11/4074; G11C 11/4094

(57) ABSTRACT

There is provided a memory device including a first memory cell connected to a first bit line; a second memory cell connected to a second bit line, a first transistor connected to the first bit line and configured to transfer a first data signal based on first data stored in the first memory cell to an input node of a bit line sense amplifier, and a second transistor connected to the second bit line and configured to transfer a second data signal based on second data to the input node. The bit line sense amplifier is configured to amplify a selected one of the first or second data signal to output a first amplified signal to a local sense amplifier through a local transistor.

### CROSS-REFERENCE TO THE RELATED APPLICATION

This application claims priority from Korean Patent Application No. 10-2024-0131672 filed on Sep. 27, 2024 in the Korean Intellectual Property Office and all the benefits accruing therefrom under 35 U.S.C. 119, the contents of which in its entirety are herein incorporated by reference.

### BACKGROUND

### 1. Field of the Disclosure

The present disclosure relates to a memory device, and specifically, to a memory device including a sensing device and a driving method.

### 2. Description of the Related Art

At the time of a read operation or a refresh operation of a memory device, a sense amplifier may sense a voltage difference between a bit line and a complementary bit line to sense data of a memory cell. Because the size of the memory cell becomes smaller and the load of bit line increases due to high integration of the memory device, it may be difficult to maintain a margin of the voltage difference. If it fails to maintain the margin of the voltage difference, data sensing of the memory cell may fail.

### SUMMARY

Aspects of the present disclosure provide a memory device having improved performance for sensing data stored in a memory cell.

Aspects of the present disclosure also provide a memory device including a sense amplifier circuit that operates at a low power.

Aspects of the present disclosure also provide a memory device having improved accuracy.

According to an aspect of the present disclosure, there is provided a memory device comprising a first memory cell connected to a first bit line, a second memory cell connected to a second bit line, a first transistor connected to the first bit line and configured to transfer a first data signal based on first data stored in the first memory cell to an input node of a bit line sense amplifier, a second transistor connected to the second bit line configured to transfer a second data signal based on second data stored in the second memory cell to the input node of the bit line sense amplifier. The bit line sense amplifier may be connected to the input node to amplify a selected one of the first data signal or the second data signal provided to the input node to output a first amplified signal. A local transistor, a be connected to an output node of the bit line sense amplifier and to an input of a local sense amplifier configured to amplify the first amplified signal to output a second amplified signal.

According to another aspect of the present disclosure, there is provided a memory device comprising a first memory cell connected to a first bit line and to store first data, a first transistor having a first terminal connected to the first bit line and configured to transfer a first data signal based on the stored first data to a second terminal, a bit line sense amplifier connected to the first transistor configured to amplify the first data signal to output a first amplified signal to an output node through a precharge transistor, and a local transistor having a first local terminal connected to the output node of the bit line sense amplifier, and a second local terminal connected to a local sense amplifier, wherein the local sense amplifier is configured to amplify the first amplified signal to output a second amplified signal, and a control logic circuit configured to control transfer of the first amplified signal to the local sense amplifier by controlling the local transistor to be in an on state and controlling the precharge transistor to be in an off state.

According to another aspect of the present disclosure, there is provided a method for driving a memory device which comprises a first memory cell connected to a first bit line and stores data, a first transistor connected to the first bit line, a bit line sense amplifier connected to the first transistor and comprising a precharge transistor, and a local transistor connected to the bit line sense amplifier and a local sense amplifier, the method comprising providing a first data signal based on the stored data to the bit line sense amplifier, when the first transistor is turned on, amplifying the first data signal by the bit line sense amplifier to obtain a first amplified signal, providing the first amplified signal to an output node of the bit line sense amplifier, when the precharge transistor is turned on, and providing an output of the bit line sense amplifier to the local sense amplifier when the local transistor has an on state and the precharge transistor has an off state to provide the first amplified signal from the output node of the bit line sense amplifier to the local sense amplifier.

### BRIEF DESCRIPTION OF DRAWINGS

The above and other aspects and features of the present disclosure will become more apparent by describing in detail illustrative embodiments thereof with reference to the attached drawings, in which:

FIG. 1 is a block diagram for explaining a memory device according to some embodiments of the present disclosure.

FIG. 2 is a diagram for explaining a memory cell array and a sense amplifier in the memory device according to some embodiments of the present disclosure.

FIG. 3 is a diagram for explaining a memory cell and a sense amplifier circuit in the memory device according to some embodiments of the present disclosure.

FIG. 4 is a perspective view showing the memory device of FIG. 1 implemented according to an embodiment.

FIG. 5 is a circuit diagram showing the memory cell array of FIG. 1 implemented according to an embodiment.

FIG. 6 is an exemplary circuit diagram 600 of the sense amplifier circuit in the memory device according to some embodiments of the present disclosure.

FIG. 7 is an exemplary timing diagram 700 for explaining a first operation of the sense amplifier circuit shown in FIG. 6.

FIG. 8 is an exemplary circuit diagram 800 showing the sense amplifier circuit in the memory device according to some embodiments.

FIG. 9 is an exemplary timing diagram for explaining the second operation of the sense amplifier circuit shown in FIG. 6.

FIGS. 10 to 13 are circuit diagrams of the sense amplifier circuit that performs the second operation.

FIG. 14 is an exemplary timing diagram for explaining a third operation of the sense amplifier circuit shown in FIG. 6.

FIG. 15 is an exemplary timing diagram for explaining a fourth operation of the sense amplifier circuit shown in FIG. 6.

FIG. 16 is an exemplary timing diagram for explaining a fifth operation of the sense amplifier circuit shown in FIG. 6.

FIG. 17 is a graph showing sensing data according to an internal power supply of the sense amplifier circuit in the memory device according to some embodiments.

FIG. 18 is a graph showing sensing data of a sense amplifier circuit in a memory device according to some embodiments.

FIG. 19 is a block diagram showing a computer device including a memory device according to some embodiments.

### DETAILED DESCRIPTION OF THE EMBODIMENTS

The contents of the present disclosure will be described below clearly and in detail so that a person having ordinary skill in the art of the present disclosure may easily carry out the present disclosure using the drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

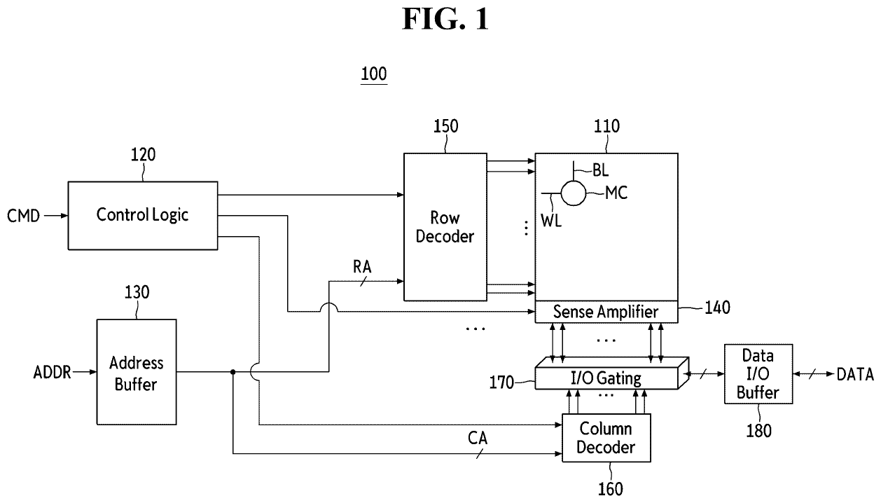

FIG. 1 is a block diagram for explaining a memory device according to some embodiments of the present disclosure.

Referring to FIG. 1, a memory device 100 may include a memory cell array 110, a control logic circuit 120, an address buffer 130, a sense amplifier 140, a row decoder 150, a column decoder 160, an input/output (I/O) gating circuit 170, and a data I/O buffer 180. In some embodiments, the memory device 100 may be an operational random-access memory (DRAM).

The memory cell array 110 may include a plurality of rows, a plurality of columns, and a plurality of memory cells MC arranged at an intersection of the plurality of rows and the plurality of columns. The plurality of rows may be defined by a plurality of word lines WL, and the plurality of columns may be defined by a plurality of bit lines BL.

The control logic circuit 120 may be an internal controller of the memory device 100, and may control the operation of the memory device 100. For example, the control logic circuit 120 may generate control signals so that the memory device 100 performs a read operation, a write operation or a refresh operation. In some embodiments, the control logic circuit 120 may generate control signals by decoding a command CMD received from the memory controller. In some embodiments, the control logic circuit 120 may transfer the control signal to the sense amplifier 140, the row decoder 150, and the column decoder 160. In some examples, the control logic circuit 120 may also be configured to control the timing of the control signals provided to the sense amplifier 140, the row decoder 150, and the column decoder 160.

The address buffer 130 may receive an address ADDR provided from the memory controller. The address ADDR may include a row address RA that indicates a row of the memory cell array 110, and a column address CA that indicates a column. The row address RA may be provided to the row decoder 150, and the column address CA may be provided to the column decoder 160.

The row decoder 150 may select a row to be activated among the plurality of rows of the memory cell array 110 on the basis of the row address RA. To this end, the row decoder 150 may apply a driving voltage to the word line WL corresponding to the row to be activated.

The column decoder 160 may select a column to be activated among the plurality of columns of the memory cell array 110 on the basis of a column address CA. To this end, the column decoder 160 may activate the sense amplifier 140 corresponding to the column address CA through the I/O gating circuit 170. The sense amplifier 140 may be connected to a bit line BL of the memory cell array 110. The sense amplifier 140 may sense a voltage of the bit line BL and output the sensed voltage. In some embodiments, the I/O gating circuit 170 may include a data latch for gating the input/output data and storing the data read from the memory cell array 110, and a write driver for writing the data on the memory cell array 110. The data that is read from the memory cell array 110 may be sensed by the sense amplifier 140 and stored in the I/O gating circuit 170 (e.g., a data latch).

In some embodiments, data that is read from the memory cell array 110 (e.g., data stored in the data latch) may be provided to the memory controller through the data I/O buffer 180. Data to be written on the memory cell array 110 is provided from the memory controller to the data I/O buffer 180, and the data provided to the data I/O buffer may be provided to the I/O gating circuit 170.

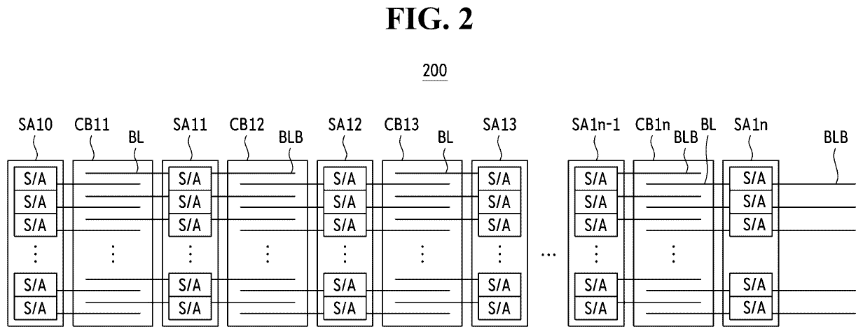

FIG. 2 is a diagram for explaining a memory cell array and a sense amplifier in the memory device according to some embodiments of the present disclosure.

Referring to FIG. 2, the memory cell array 200 may include a plurality of memory cell blocks CB11, CB12, CB13, . . . CB1n and a plurality of sense amplifier blocks SA10, SA11, SA12, . . . SA1n−1, SA1n (here, n is a positive integer). Each sense amplifier block SA1i corresponds to two adjacent memory cell blocks CB1i and CB1i+1 among the plurality of memory cell blocks CB11 to CB1n, and may be connected to the two adjacent memory cell blocks CB1i and CB1i+1 (here, i is an integer from 1 to (n−1)).

Each memory cell block CB1i may include a plurality of bit lines BL extending in a predetermined direction (e.g., a column direction). A plurality of memory cells may be connected to each bit line BL. The memory cell block CB1i may further include a plurality of word lines extending in a different direction (e.g., a row direction). Each of the plurality of memory cells connected to each bit line BL may be connected to one word line WL of the plurality of word lines.

In some embodiments, as shown in FIG. 2, some of the plurality of memory cell blocks CB10 to CB1n may include complementary bit lines BLB as bit lines. For example, the complementary bit lines BLB may be functionally equivalent to the bit lines BL, but may be distinguished based on their location and/or connections to the respective sense amplifier blocks, as described herein. In this case, the memory cell blocks in which the bit lines BL are formed are disposed alternately with the memory cell blocks in which the complementary bit lines BLB are formed, and the bit lines BL and the complementary bit lines BLB may form complementary bit line pairs. Each sense amplifier block SA1i may be connected to the bit lines BL and the complementary bit lines BLB. For example, each sense amplifier block SA1i may be configured to sense data from a bit line BL and/or a complementary bit line BLB connected to sense amplifier block SA1i, as described herein.

The sense amplifier block SA1i may be connected to some bit lines BL of one memory cell block CB1i and some complementary bit lines BLB of the adjacent memory cell block CB1i+1. In some embodiments, the sense amplifier block SA1i may be connected to odd-numbered bit lines BL of the memory cell block CB1i (e.g., numbering the bit lines BL in a consistent way, such as from the top of the memory cell block CB1i in the example of FIG. 2) and odd-numbered complementary bit lines BLB of the memory cell block CB1i+1 (e.g., numbering the complementary bit lines BLB in a consistent way, such as from the top of the memory cell block CB1i+1). In this case, the even-numbered bit lines BL of the memory cell block CB1i may be connected to an adjacent sense amplifier block SA1i−1, and the even-numbered complementary bit lines BLB of the memory cell block CB1i+1 may be connected to another adjacent sense amplifier block SA1i+1. Alternatively, in another embodiment, the sense amplifier block SA1i may be connected to the even-numbered bit line BL of the memory cell block CB1i and the even-numbered complementary bit line BLB of the memory cell block CB1i+1.

In some embodiments, the sense amplifier block SA10 located at a first end may be connected to the bit line BL of one memory cell CB11, and the sense amplifier block SA1n located at the other end may be connected to the complementary bit line BLB of one memory cell CB1n.

The sense amplifier block SA1i may include a plurality of sense amplifiers S/A. Each of the plurality of sense amplifiers S/A may correspond to some bit lines BL of the memory cell block CB1i, and may correspond to some complementary bit lines BLB of the adjacent memory cell block CB1i+1. Each sense amplifier S/A may be connected to the corresponding complementary bit line BLB among some complementary bit lines (e.g., the odd-numbered complementary bit lines) BLB of the memory cell block CB1i+1 that are different from the corresponding bit line BL among some bit lines (e.g., the odd-numbered bit lines) BL of the memory cell block CB1i.

In some embodiments, the plurality of sense amplifiers S/A may be connected to the bit line BL and the complementary bit line BLB. The plurality of sense amplifiers S/A included in the sense amplifier block SA1i may be single-ended, for example each of the bit line BL and the complementary bit line BLB may be connected to the first node N1. In some embodiments, the plurality of sense amplifiers S/A located at the end of the memory device may be single-ended. For example, the plurality of sense amplifiers S/A included in an n-th sense amplifier block SA1n may be single-ended, for instance the bit line BL or the complementary bit line BLB may be connected to the sense amplifier S/A. The present disclosure may be a structure that is applicable to a plurality of sense amplifiers S/A.

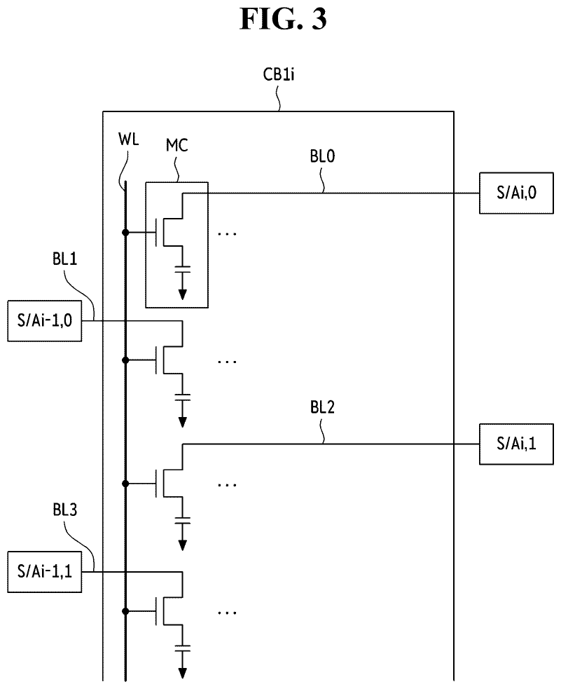

FIG. 3 is a diagram for explaining a memory cell and a sense amplifier circuit in the memory device according to some embodiments of the present disclosure.

As shown in FIG. 3, each of the bit lines BL0 and BL2 in the cell array block CB1i may be connected to the sense amplifiers S/Ai,0 and S/Ai,2 of the sense amplifier block SA1i, and each of the bit lines BL1 and BL3 may be connected to the sense amplifiers S/Ai-1,0 and S/Ai-1,1 of the sense amplifier block SA1i−1. FIG. 3 shows one word line WL and a memory cell MC connected to the word line WL for convenience of explanation. Although FIG. 3 shows that each memory cell MC includes a transistor and a capacitor, the structure of the memory cell MC is not limited thereto.

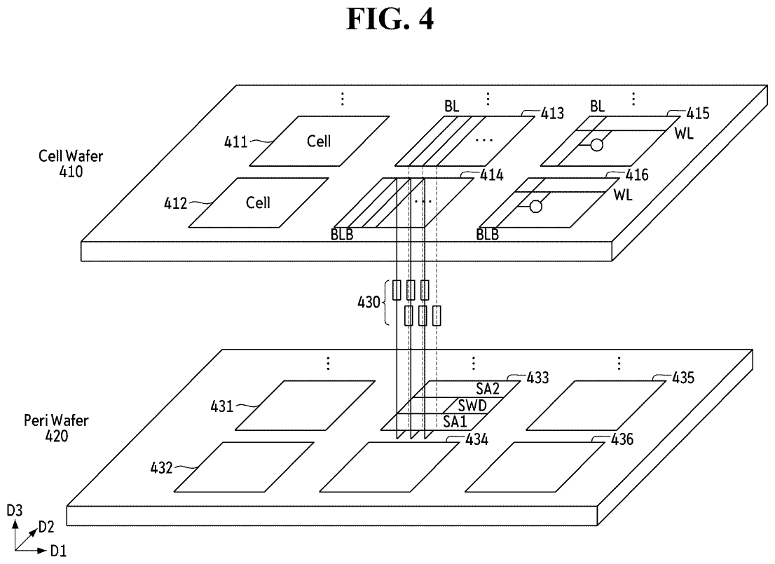

FIG. 4 is a perspective view showing the memory device of FIG. 1 implemented according to an embodiment.

Referring to FIGS. 1 to 3, the memory device (100 of FIG. 1) may include a cell wafer 410, a peri (e.g., peripheral) wafer 420, and a bonding pad 430 which electrically connects the cell wafer 410 and the peri wafer 420.

The cell wafer 410 may include a plurality of memory cell regions 411 to 416. Some memory cell regions 411, 413, and 415 among the plurality of memory cell regions 411 to 416 may include a plurality of word lines WL, a plurality of bit lines BL, and a plurality of memory cells MC disposed at the intersections of the plurality of word lines WL and the plurality of bit lines BL. The remaining memory cell regions 412, 414, and 416 except for some memory cell regions 411, 413, and 415 among the plurality of memory cell regions 411 to 416 may include a plurality of word lines WL, a plurality of complementary bit lines BLB, and a plurality of memory cells MC disposed at the intersections of the plurality of word lines WL and the plurality of complementary bit lines BLB. The cell wafer 410 and the peri wafer 420 may be disposed to overlap each other along a third axis D3 direction and may be bonded to each other.

The peri wafer 420 may include a plurality of peri (e.g., peripheral) regions 431 to 436. Each of the plurality of peri regions 431 to 436 may include a sub-word line driver region SWD disposed along a second axis D2 direction, and sense amplifier regions SA1 and SA2 disposed along a first axis D1 direction. A plurality of sub-word line drivers may be disposed in the sub-word line driver region SWD. The plurality of sub-word line drivers may activate a specific word line among the plurality of word lines. A plurality of sense amplifier circuits may be disposed in the sense amplifier regions SA1 and SA2. The plurality of sense amplifier circuits may discriminate the status of memory cells connected to the plurality of bit lines BL or the plurality of complementary bit lines BLB.

The sense amplifier regions SA1 and SA2 may be electrically connected to some of the plurality of memory cell regions 411 to 416 through the bonding pad 430. At this time, the sense amplifier regions SA1 and SA2 may be connected to the bit lines BL and complementary bit lines BLB included in the plurality of memory cell regions 411 to 416.

For example, the sense amplifier regions SA1 and SA2 of the first peri region 433 may be electrically connected to the bit lines BL of the third memory cell region 413 and the complementary bit lines BLB of the fourth memory cell region 414 that are adjacent to each other in the second axis direction D2 direction. In some examples, each pair of a bit line BL and a complementary bit line BLB that are connected to the same sense amplifier may be aligned with each other in the second axis direction D2.

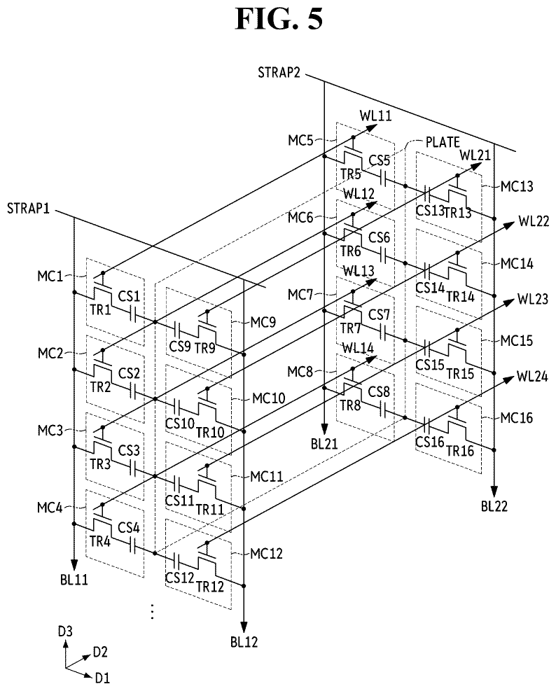

FIG. 5 is a circuit diagram showing the memory cell array of FIG. 1 implemented three-dimensionally, according to an embodiment.

Referring to FIG. 5, the memory cell array 500 may include a plurality of memory cells MC1 to MC16 stacked in the third axis D3 direction. The plurality of memory cells MC1 to MC16 may be connected to a plurality of bit line segments BL11, BL12, BL21, and BL22 disposed along the third axis D3 direction. For example, first to fourth memory cells MC1 to MC4 may be connected to a first bit line segment BL11, and fifth to eighth memory cells MC5 to MC8 may be connected to a second bit line segment BL21. In addition, ninth to twelfth memory cells MC9 to MC12 may be connected to a third bit line segment BL12, and thirteenth to sixteenth memory cells MC13 to MC16 may be connected to a fourth bit line segment BL22.

The first bit line segment BL11 and the third bit line segment BL12 may be connected to a first strap STRAP1 disposed along the first axis D1 direction. In addition, the second bit line segment BL21 and the fourth bit line segment BL22 may be connected to a second strap STRAP2 disposed along the first axis D1 direction. The number of bit lines connected to the first strap STRAP1 and the second strap STRAP2 and the number of memory cells connected to the bit lines are merely examples.

A plurality of word lines WL11, WL12, WL13, WL14, WL21, WL22, WL23, and WL24 are disposed along the second axis D2 direction, and may apply a voltage to the gates of the transistors TR1 to TR16 included in the plurality of memory cells MC1 to MC16.

The word lines WL11, WL12, WL13, and WL14 may be connected to the transistors TR1 to TR4 connected to the first bit line segment BL11, and the transistors TR5 to TR8 connected to the third bit line segment BL21. For example, the first word line WL11 may be connected to the gate of the first transistor TR1 and the gate of the fifth transistor TR5, and the second word line WL12 may be connected to the gate of the second transistor TR2 and the gate of the sixth transistor TR6. In addition, the third word line WL13 may be connected to the gate of the third transistor TR3 and the gate of the seventh transistor TR7, and the fourth word line WL14 may be connected to the gate of the fourth transistor TR4 and the gate of the eighth transistor TR8. Similarly, the word lines WL21, WL22, WL23, and WL24 may be connected to the transistors TR9 to TR12 connected to the second bit line segment BL12, and the transistors TR13 to TR16 connected to the fourth bit line segment BL22. In some embodiments, the respective bit line segments that are connected to a single respective strap in the example of FIG. 5 may correspond to a single bit line BL or complementary bit line BLB, such as those described elsewhere herein, for example in FIG. 2. For example, the first bit line segment BL11 and the second bit line segment BL12, which are connected to the first strap STRAP1, may correspond to a single bit line (e.g., BL1) or complementary bit line (e.g., BLB1). Likewise, the third bit line segment BL21 and the fourth bit line segment BL22, which are connected to the second strap STRAP2, may correspond to a single bit line (e.g., BL2) or complementary bit line (e.g., BLB2).

The capacitors CS1 to CS16 included in each of the memory cells MC1 to MC16 may be connected to the transistors TR1 to TR16 included in each of the memory cells MC1 to MC16 in the first axis D1 direction, which is a direction perpendicular to the third axis D3 direction along which the plurality of memory cells MC1 to MC16 are stacked. For example, each of the first capacitor CS1 to the fourth capacitor CS4 may be connected to the first transistor TR1 to the fourth transistor TR4 along the first axis D1 direction, and each of the fifth capacitor CS5 to the eighth capacitor CS8 may be connected to the fifth transistor TR5 to the eighth transistor TR8 along the first axis D1 direction. In addition, each of the ninth capacitor CS9 to the twelfth capacitor CS12 may be connected to the ninth transistor TR9 to the twelfth transistor TR12 along the first axis D1 direction, and each of the thirteenth capacitor CS13 to the sixteenth capacitor CS16 may be connected to the thirteenth transistor TR13 to the sixteenth transistor TR16 along the first axis D1 direction.

When each of the first capacitor CS1 to the sixteenth capacitor CS16 are connected to the first transistor TR1 to the sixteenth transistor TR16 along the first axis D1 direction, a chip space efficiency of the memory cell array 500 may be improved. When the chip space efficiency is improved, the number of memory cells MC1 to MC16 that may be integrated per unit area increases, and so the overall memory capacity may be improved.

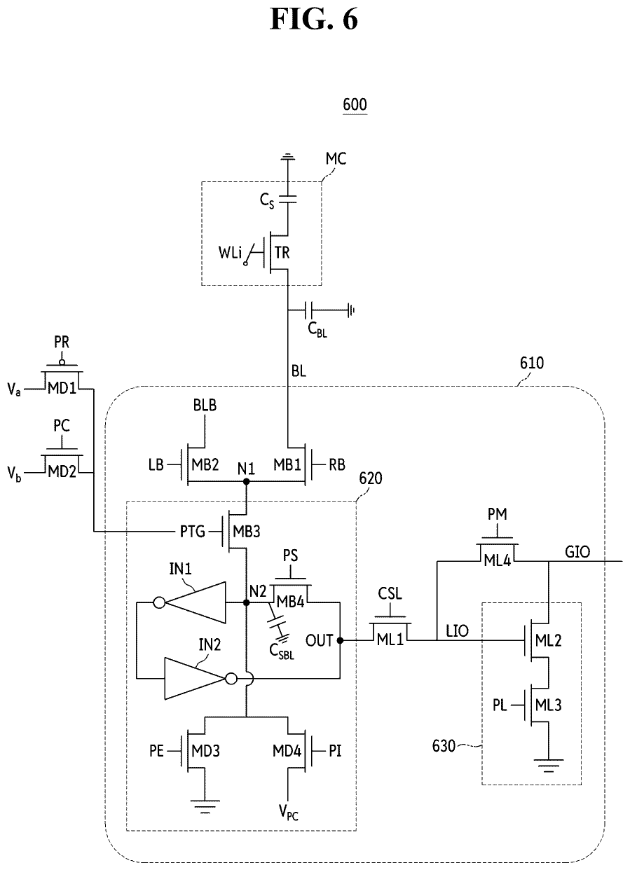

FIG. 6 is an exemplary circuit diagram 600 of the sense amplifier circuit in the memory device according to some embodiments of the present disclosure.

Referring to FIG. 6, a sense amplifier circuit 610 may include a bit line sense amplifier circuit 620, a local transistor ML1, and a local sense amplifier circuit 630. Sense amplifier circuit 610 may be connected to control logic circuit 120 to receive the control signals discussed in detail below (which may be directly or indirectly connected, such as through I/O gating circuit 170 for control signal CSL).

One end of the bit line sense amplifier circuit 620 may be connected to a plurality of memory cells MC through the bit line BL and the complementary bit line BLB. Each of the plurality of memory cells MC may include a transistor TR and a capacitor CS. The other end of the bit line sense amplifier circuit 620 may be electrically connected to a local I/O line LIO. A voltage of an output node OUT of the bit line sense amplifier circuit 620 may be transferred to the local I/O line LIO through the local transistor ML1. Furthermore, in some embodiments, the bit line sense amplifier circuit 620 may have a single input (a single input node) connected to the bit line BL and the complementary bit line BLB through a bit line transistor MB1 and a complementary bit line transistor MB2.

The bit line transistor MB1 and the complementary bit line transistor MB2 may be electrically connected to a first node N1, e.g., an input node of the bit line sense amplifier circuit 620. For example, one end (e.g., a source/drain, also referred to as a S/D) of the bit line transistor MB1 may be connected to the first node N1, and the other end (e.g., a S/D) thereof may be connected to the bit line BL. One end (e.g., a S/D) of the complementary bit line transistor MB2 may be connected to the first node N1, and the other end (e.g., a S/D) thereof may be connected to the complementary bit line BLB. The bit line transistor MB1 may operate by (e.g., be gated by) a first control signal RB. The complementary bit line transistor MB2 may operate by (e.g., be gated by) a second control signal LB.

For example, the bit line sense amplifier circuit 620 may include a control transistor MB3, a first inverter IN1, a second inverter IN2, a precharge transistor MB4, a first transistor(MD3), and a second transistor(MD4).

The control transistor MB3 may be connected to the bit line BL through the bit line transistor MB1. Thus, the bit line BL may be selectively connected to node N2 through control transistor MB3 and bit line transistor MB1. The control transistor MB3 may also be connected to the complementary bit line BLB through the complementary bit line transistor MB2. Thus, the complementary bit line BBL may be selectively connected to node N2 through control transistor MB3 and complementary bit line transistor MB2.

The control transistor MB3 may selectively connect the first node N1 to the second node N2 (control transistor MB3 may be connected between nodes N1 and N2).

A fifth control signal PTG may be applied to a gate of the control transistor MB3. The fifth control signal PTG may be the bias voltage Vb of the control transistor MB3 or a supply voltage Va having a higher voltage level than the bias voltage Vb. The bias voltage Vb may be provided through a fourth transistor MD2 turned on based on the control signal PC of the active level. The supply voltage Va may be provided through a third transistor MD1 turned on based on the control signal PR of the active level. The bias voltage Vb and the supply voltage Va may be generated from separate voltage generators (not shown).

The first transistor(MD3) may be connected between the second node N2 and a ground terminal (e.g., VSS), and the second transistor(MD4) may be connected between the second node N2 and a line supplying the precharge voltage Vpc. The first transistor(MD3) may transfer the first voltage VSS to the second node N2 in response to the control signal PE having an active state (e.g., logic high), and the second transistor(MD4) may transfer the precharge voltage Vpc to the second node N2 in response to the control signal PI having an active state (e.g. logic high).

For example, the first transistor(MD3) may be an NMOS transistor and have a drain connected to the second node N2, a source connected to a ground terminal (e.g., VSS), and a gate connected to receive the control signal PE. Also, in the second transistor(MD4) may be an NMOS transistor and have a drain may be connected to a line supplying a precharge voltage Vpc, a source may be connected to a second node N2, and a gate connected to receive the control signal PI.

The first inverter IN1 may be connected to the second node N2. For example, an input terminal of the first inverter IN1 may be connected to the second node N2. In some embodiments, the input terminal of the first inverter IN1 may be connected to the control transistor MB3 and the precharge transistor MB4 through the second node N2. In some embodiments, the first inverter IN1 may be a complementary MOS (CMOS) inverter.

The second inverter IN2 may be connected to the first inverter IN1 and the output node OUT. For example, an input terminal of the second inverter IN2 may be connected to an output terminal of the first inverter IN1. For example, by inverting the signal twice, it may be logically equivalent to (e.g., unchanged from) the input of the first inverter IN1, other than being amplified. An output terminal of the second inverter IN2 may be connected to the output node OUT of the bit line sense amplifier circuit 620. For example, the output of the two inverters IN1 and IN2 in series may be provided as the output of bit line sense amplifier circuit 620. In some embodiments, the output terminal of the second inverter IN2 may be connected to the precharge transistor MB4. In some embodiments, the second inverter IN2 also may be a complementary MOS (CMOS) inverter. The first inverter IN1 may be connected to the second inverter IN2 may form a data latch that sense and latches a data signal provided by a corresponding memory cell MC on the bit line BL or on the complementary bit line BLB.

The precharge transistor MB4 is connected between the second node N2 and the output node OUT of the bit line sense amplifier circuit 620, and may operate in response to a third control signal PS of the precharge transistor MB4. For example, one end of the precharge transistor MB4 may be connected to the second node N2, and the other end of the precharge transistor MB4 may be connected to the output node OUT of the bit line sense amplifier circuit 620. The gate of the precharge transistor MB4 may receive the third control signal PS.

The bit line sense amplifier circuit 620 may further include a capacitance component CSBL of the second node N2. The second node N2 may be connected to the precharge transistor MB4. The second node N2 may also be connected to the control transistor MB3. The capacitance component CSBL of the second node N2 may store the charge according to the connectivity of the second node N2. Also, the capacitance component CSBL of the second node N2 may transfer the stored charges according to the connectivity of the second node N2.

A column selection line CSL is connected to the gate of the local transistor ML1, and the operation of the local transistor ML1 may be determined on the basis of the potential of the column selection line CSL. For example, when the column selection line CSL is a voltage of a logic high level, the local transistor ML1 may be turned on, and when the column selection line CSL is a voltage of a logic low level, the local transistor ML1 may be turned off. The column selection line CSL may be called a fourth control signal. The local transistor ML1 may transfer data sensed by the bit line sense amplifier circuit 620 to the local I/O line LIO. The voltage of the bit line BL may be changed at the time when the charge is shared by the local I/O line. In some embodiments, the third control signal PS may maintain an inactive level (e.g., a low level) when a fourth control signal CSL of an active level (e.g., a high level) is applied, thereby preventing the data value sensed by the disclosed bit line sense amplifier circuit 620 from spuriously changing in response to a change of the fourth control signal CSL to the active level.

The local sense amplifier circuit 630 may amplify the voltage of the local I/O line LIO in response to a sixth control signal PL and transfer it to the global I/O line GIO. The local sense amplifier circuit 630 may include transistors ML2 and ML3 connected in series. The ML2 transistor may be connected to the ML3 transistor and the local I/O line control transistor ML4. A LIO line may be applied to the ML2 transistor as a control signal. The ML3 transistor may be connected to the MN2 transistor and the ground voltage. A control signal PL may be applied to the ML3 transistor.

The local I/O line control transistor ML4 may control the connection between the local I/O line LIO and the global I/O line GIO in response to a seventh control signal PM.

For example, when the sixth control signal PL is at a high level and the seventh control signal PM is at a low level, the local sense amplifier circuit 630 is activated, and the local I/O line control transistor ML4 may block the connection between the local I/O line LIO and the global I/O line GIO.

For example, when the sixth control signal PL is at a low level and the seventh control signal PM is at a high level, the local sense amplifier circuit 630 is inactivated, and the local I/O line control transistor ML4 may provide the connection between the local I/O line LIO and the global I/O line GIO.

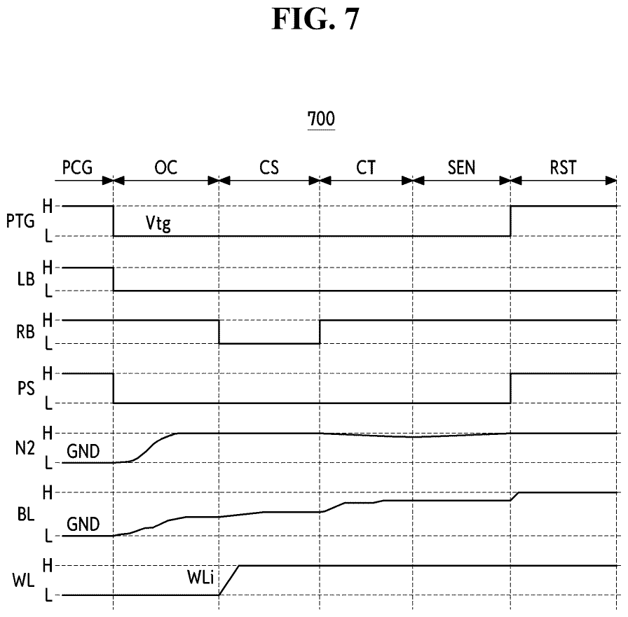

FIG. 7 is an exemplary timing diagram 700 for explaining a first operation of the sense amplifier circuit shown in FIG. 6. With the exception of voltage Vtg of fifth control signal PTG, the high (H) and low (L) levels of the signals depicted in FIG. 7 may respectively correspond to logic high voltages (e.g., VDD) and logic low voltages (e.g., VSS). The voltage level of Vtg may be slightly higher than a logic low voltage as discussed below.

A first operation OP1 of the sense amplifier circuit 610 may sequentially perform a precharge operation PCG, an offset compensation operation OC, a charge sharing operation CS, a charge transfer operation CT, a sensing operation SEN, and a restoring operation RST. Data “1”or data “0”may be stored in the memory cell MC in FIG. 7.

Referring to FIGS. 6 and 7, the sense amplifier circuit 610 may perform a precharge operation PCG for precharging the bit line BL, the complementary bit line BLB, the first node N1, the second node N2 and the output node OUT with the ground voltage VSS.

Specifically, during a precharge operation (PCG), the first transistor(MD3) may be turned on based on the control signal PE having an active level (e.g., a high level). Accordingly, the first transistor(MD3) may connect the ground voltage VSS to the second node N2 and precharge the second node N2 to the ground voltage VSS. At this time, the second transistor may be off.

Additionally, during the precharge operation PCG period, a fifth control signal PTG of an active level (e.g., a high level) is applied to the gate of the control transistor MB3, and the control transistor MB3 may be turned on. Accordingly, the first node N1 may be precharged with the ground voltage VSS through the first transistor(MD3) connecting the second node N2 to the ground voltage VSS.

During the precharge operation PCG period, the bit line transistor MB1 and the complementary bit line transistor MB2 may be turned on, on the basis of the first and second control signals RB and LB of an active level (e.g., a high level). Accordingly, the bit line BL and the complementary bit line BLB may be precharged with the ground voltage VSS through the first node N1. The capacitance component CBL present in the bit line BL is thus precharged with the ground voltage VSS.

During the precharge operation PCG period, the precharge transistor MB4 may be turned on, on the basis of the third control signal PS of an active level (e.g., a high level). Accordingly, the output node OUT may also be precharged to the ground voltage VSS.

Referring to FIGS. 6 and 7, the sense amplifier circuit may perform an offset compensation operation OC. The sense amplifier circuit may perform an offset compensation operation OC that connects the bit line BL and the second node N2 through the control transistor MB3 to store offset information of the first control transistor MB3.

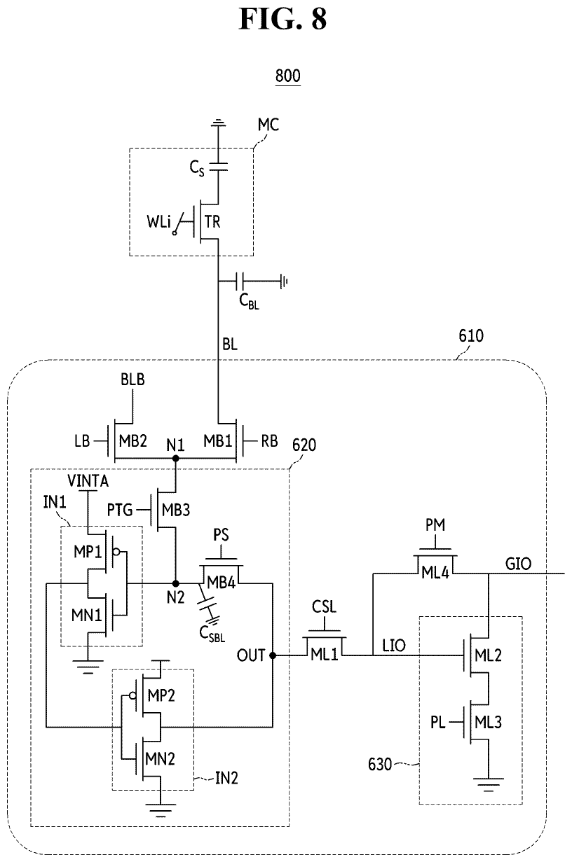

Specifically, during an offset compensation operation OC, the second transistor(MD4) may be turned on based on the control signal PI of an active level (e.g., a high level) and the first transistor(MD3) may be turned off (based on the control signal PE having an inactive level). Accordingly, the precharge voltage Vpc may be precharged to the second node N2 via the second transistor(MD4). The precharge voltage Vpc may be higher than the supply voltage VINTA (see FIG. 8).

The control transistor MB3 to which the fifth control signal PTG is applied may be in a weakly turned-on status. The fourth transistor MD2 may be turned on based on the control signal PC of the active level (e.g., the high level), and the third transistor MD1 may be turned off based on the control signal PR of the inactive level (e.g., the high level). Accordingly, the bias voltage Vb may be applied to the gate of the control transistor MB3 as a control signal PTG. The bias voltage Vb may be a voltage between a voltage of a high level used as an active level and a voltage of a low level used as an inactive level, and may be higher than the threshold voltage Vth of the complementary bit line transistor MB2. However, the bias voltage Vb may be lower than the supply voltage VDD. In some embodiments, the bias voltage Vb may be set in consideration of charge transfer in a charge transfer operation CT to be described below.

As a result, a current may flow from the second node N2, to which the precharge voltage is applied, to the first node N1 (at ground voltage VSS during the start of the offset compensation operation OC) and the voltage of the first node N1 may increase. As the voltage of the first node N1 increases, the voltage of the first node N1 may reach a certain level to cause control transistor MB3 to turn off. Specifically, if the difference between the voltage of the first node N1 (connected to the source of the control transistor MB3) and the voltage Vtg of fifth control signal PTG is smaller than the threshold voltage Vth of the control transistor MB3, the control transistor MB3 is turned off. Thus, the voltage of the first node is N1 is increased until the voltage at first node N1 equals Vtg−Vth_{MB3} (where Vth_{MB3} is the threshold voltage Vth of control transistor MB3). In addition, during the offset compensation operation OC, bit line BL is connected to the first node N1 through transistor MB1 (which is on due to RB having an active state (e.g., high)) and is charged to the same value as first node N1 (Vtg−Vth_{MB3}). Thus, during the offset compensation operation OC, the voltage of the first node N1 and the bit line BL is increased and set to a value (Vtg−Vth_{MB3}) corresponding to (and innately including information about) the threshold voltage of control transistor MB3. Thus, the control transistor MB3 may be turned on, until a difference between voltage of the first node N1 and voltage Vtg applied to the gate of the first control transistor MB3 reaches a threshold voltage of the first control transistor MB3. During the offset compensation operation OC, the bit line BL may be in the form of an electrical stub, connected at only one end of the bit line (having being electrically connected only to node N1 via transistor MB1). Thus, the offset compensation operation OC may provide and store a voltage on the bit line BL that corresponds to the threshold voltage of the first control transistor MB3.

During the offset compensation operation OC period, the complementary bit line transistor MB2 and the precharge transistor MB4 may be turned off, on the basis of the second and third control signals LB and PS at an inactive level (e.g., a low level). The bit line transistor MB1 may be maintained in a turned-on status on the basis of the first control signal RB of an active level (e.g., a high level). In some examples, the disclosed input sense amplifier may operate only one of the bit line BL or complementary bit line BLB to perform sensing, which may reduce power consumption. For example, both the bit line BL and the complementary bit line BLB may be selectively electrically connected to the first node N1 (e.g., the input node of the bit line sense amplifier circuit 620) in a single-ended configuration, and therefore only one of them may be sensed at a time. Accordingly, one of the first control signal RB or the second control signal LB may be changed to an inactive level (e.g., a low level) in preparation for the sense operation SEN. In this example, during the offset compensation operation OC period, the first control signal RB is maintained in an active level (connecting bit line BL to node N1) and the second control signal LB is changed to an inactive level (maintaining the disconnect of complementary bit line BLB from node N1).

Accordingly, the precharge voltage applied to the second node N2 may be connected to the bit line BL through the control transistor MB3, the first node N1, and the bit line transistor MB1 such that the voltage applied to the bit line BL corresponds to the precharge voltage reduced at least by the threshold voltage of control transistor MB3.

The precharge voltage Vpc may be connected to the bit line BL until the difference between the voltage PTG and the voltage of the first node N1 and the voltage of the second node N2 reaches the threshold voltage Vth of the control transistor MB3. It will be appreciated that the bit line BL will not be charged to the full precharge voltage Vpc due to the voltage drop(s) applied to the precharge voltage Vpc signal from node N2 to the bit line BL (such as the voltage drop provided by the threshold voltage Vth_{MB3} of control transistor MB3) and references herein of connecting the precharge voltage Vpc to the bit line BL will be understood to encompass such voltage drop(s) (i.e., such a connection need not result in the full voltage being transmitted).

The voltage of the bit line BL may be determined by the threshold voltage Vth_{MB3}of the control transistor MB3. When the bit line BL does not need compensation for the threshold voltage Vth_{MB3}of the control transistor MB3, the offset compensation operation OC may be omitted.

Referring to FIGS. 6 and 7, the sense amplifier circuit may perform a charge sharing operation CS which shares the charges between the bit line BL and the memory cell MC. At this time, the word line WLi connected to the gate of the memory cell MC may be activated, turning on the transistor TR of memory cell MC to connect the memory cell capacitor CS to the bit line BL.

During the charge sharing operation CS period, the bit line transistor MB1 may be turned off, on the basis of the first control signal RB of an inactive level (e.g., a low level). Since the bit line transistor MB1 is turned off, the bit line BL may be electrically blocked from the first node N1 and the second node N2.

Since the transistor TR of the memory cell MC is turned on by the activation of the word line WLi connected to the gate of the memory cell MC, charges may be shared between the capacitor CS of the memory cell MC and the capacitance component CBL of the bit line. When data “1” is stored in the memory cell MC, charges (e.g., electrons) may be transferred to the capacitor CS from the bit line BL and the voltage of the bit line BL may slightly increase above Vtg−Vth_{MB3}. When data “0” is stored in the memory cell MC, charges (e.g., electrons) may be transferred from the capacitor CS to the bit line BL and the voltage of the bit line BL may slightly decrease below Vtg−Vth_{MB3}.

In the case where data “1” is stored, and the bit line BL is precharged to a voltage closer to the ground voltage VSS in the offset compensation operation OC period (e.g., precharged to Vtg−Vth_{MB3} in this example), the voltage of the bit line BL may be increased in a greater amount as compared to the case where the bit line BL is precharged with an intermediate voltage between the high level and the low level in the precharge operation PCG. Thus, the voltage value of control signal PTG applied to the control transistor MB3 may be set (during the offset compensation operation OC period) at a voltage Vtg that provides a precharge voltage to the bit line BL close to the ground voltage. Vtg may be a voltage greater than the expected threshold voltage Vth_{MB3} of control transistor MB3 by a small predetermined offset (such as in a range of 0.1 to 0.3 volts) (i.e., Vtg=expected Vth_{MB3}+Voffset, (where Voffset=0.1V to 0.3V)). The expected threshold voltage Vth_{MB3} may be the threshold voltage of control transistor MB3 (that is expected from the design of the memory device 100), but may be different from the actual threshold voltage Vth_{MB3} of control transistor MB3 due to typical variations that may occur during the manufacturing of the memory device 100. Thus, the voltage of the bit line BL may be charged during the offset compensation operation OC period to Vtg−Vth_{MB3}. The voltage of the bit line BL thus may have a voltage corresponding to Voffset (e.g., corresponding to 0.1V to 0.3V, as varied by any difference between the expected and actual threshold voltages of control transistor MB3) and thus the voltage of the bit line BL may have a voltage close to the ground voltage VSS.

During the charge sharing operation CS period, the control signal PI applied to the gate of the second transistor may continue to have an active level (e.g., high level) and thus the second transistor may remain turned on based. Accordingly, the precharge voltage Vpc may be continuously applied to the second node N2 during the charge sharing operation CS period, and the second node N2 may be precharged to the precharge voltage Vpc.

In addition, since the bit line transistor MB1 and the complementary bit line transistor MB2 are turned off, the voltage of node N1 is floated and remains at the voltage obtained during the offset compensation operation OC, a voltage high enough to maintain MB3 in an off state (e.g., node N1 remains at Vtg−Vth_{MB3}), and thus current does not flow through the control transistor MB3.

Referring to FIGS. 6 and 7, the sense amplifier circuit may perform a charge transfer operation CT that connects the bit line BL and the second node N2 to transfer charges between the bit line BL and the second node N2.

During the charge transfer operation CT, the second transistor may be turned off based on a control signal PI of an inactive level (e.g., a low level). Accordingly, the precharge voltage Vpc may not be applied to the second node N2 through the second transistor. However, the second node N2 at least initially will start the charge transfer operation CT with the precharge voltage Vpc (second node N2 having been precharged to voltage Vpc during the charge sharing operation CS), and thus the voltage of the second node N2 may start the charge transfer operation CT greater than the voltage of the first node N1.

During the charge transfer operation CT, the bit line transistor MB1 may be turned on, on the basis of the first control signal RB of the active level (e.g., a high level). Accordingly, the first node N1 may be electrically connected to the bit line BL. Vtg continues to be applied to the gate of the control transistor MB3. As discussed in more detail below, during the charge transfer operation CT, node N2 is will remain substantially at Vpc when data “1” has been stored and will decrease to a voltage substantially at or close to Vtg when data “0” has been stored. Vpc may correspond to (be interpreted as) a logic “high” and Vtg may correspond to (be interpreted as) a logic “low” (it should be appreciated that these voltages need not be the same as VDD and VSS).

When data “1” has been stored by the memory cell MC, the voltage of the bit line BL slightly increases during the charge sharing operation CS (e.g., slightly increases from Vtg−Vth_{MB3} to Vtg−Vth_{MB3}+deltaᵢ). Thus, when node N1 is connected to the bit line BL during the charge transfer operation CT (since bit line transistor MB1 is turned on), node N1 also slightly increases (e.g., slightly increases from Vtg−Vth_{MB3} to Vtg−Vth_{MB3}+deltaᵢ′). In this instance, because the voltage difference between the gate of control transistor MB3 and the voltage at node N1 is less than the threshold voltage Vth_{MB3} of control transistor MB3, control transistor MB3 remains off and node N2 continues to maintain its floating state and maintain its precharge voltage of Vpc (or substantially the same—as minor current leakage may occur, the voltage of node N2 may slightly decrease during charge transfer operation CT).

When data “0” has been stored by the memory cell MC, the voltage of the bit line BL slightly decreases during the charge sharing operation CS (e.g., slightly deceases from Vtg−Vth_{MB3} to Vtg−Vth_{MB3}−delta_{d}). Thus, when node N1 is connected to the bit line BL during the charge transfer operation CT (since bit line transistor MB1 is turned on), node N1 also slightly decreases (e.g., slightly decreases from Vtg−Vth_{MB3} to Vtg−Vth_{MB3}−delta_{d}′). In this instance, because the voltage difference between the gate of control transistor MB3 and the voltage at node N1 is greater than the threshold voltage Vth_{MB3} of control transistor MB3, control transistor MB3 is turned on and node N2 is connected to N1. With control transistor MB3 turned on, the voltage of N2 is reduced to about the voltage of node N1 and bit line BL (to about Vtg−Vth_{MB3}−delta_{d}′). Specifically, the node N2, node N1 and the bit line BL are connected together as one node by the charge sharing operation CS when data “0” has been stored, and thus share charges to equalize their voltage levels - this may continue until the node N2, node N1 and the bit line BL reach the same voltage level or charge transfer operation CT terminates and sense operation SEN begins. Because the bit line BL capacitance is substantially larger than the capacitances of node N2 (as well as node N1), the higher voltage Vpc on node N2 has minimal influence on the voltage of the bit line BL while the lower voltage of the bit line BL highly influences the voltage on node N2 to reduce the voltage of N2 to a value close to Vtg−Vth_{MB3}−delta_{d}′. Since the capacitance component of the second node N2 CSBL is less than the capacitance component CBL of the bit line BL, the voltage reduction amount of the second node N2 may be lower than the voltage increase amount of the bit line BL.

In the case of data “0”, since the bit line BL is charged with a voltage determined by the threshold voltage Vth_{MB3}in the offset compensation operation OC (e.g., to Vtg−Vth_{MB3}), a gate to source voltage of control transistor MB3 slightly greater than the threshold voltage Vth_{MB3}of the control transistor MB3 (Vth_{MB3}) may be assuredly provided (i.e., the difference of the gate voltage Vtg of control transistor MB3 and the source voltage of MB3 (at node N1)) to assure that control transistor MB3 is turned on and thereby allow node N2 to drain and reduce its voltage to a logic low level. Similarly, in the case of data “1”, such charging of the bit line BL also assures that control transistor MB3 remains off as a gate to source voltage of control transistor MB3 slightly less than the threshold voltage Vth_{MB3} of the control transistor MB3 (Vth_{MB3}) is assuredly provided (i.e., the difference of the gate voltage Vtg of MB3 and the source voltage of control transistor MB3 (at node N1)). It should be appreciated that process variations may cause the actual threshold voltage Vth_{MB3} to vary (from the designed threshold voltage and/or from device to device), but such variations are naturally addressed by this operation OP1 (e.g., by precharging the bit line BL to Vtg−Vth_{MB3} during the offset compensation operation OC).

Referring to FIGS. 6 and 7, the sense amplifier circuit may perform a sensing operation SEN that outputs the voltage of the output node OUT.

During the sense operation SEN period, supply voltages are provided the first inverter IN1 and the second inverter IN2 to sense and amplify the voltage on node N2. In the case of data ‘1’, node N2 has a voltage corresponding to a logic high (a voltage of Vpc) and thus the first inverter IN1 outputs a logic low to the second inverter IN2, and the second inverter IN2 outputs a logic high on output node OUTPUT. In the case of data ‘0’, node N2 has a voltage corresponding to a logic low (e.g., a voltage of lower than Vtg, such as about Vtg−Vth_{MB3}) and thus the first inverter IN1 outputs a logic high to the second inverter IN2, and the second inverter IN2 outputs a logic low on output node OUTPUT.

Referring to FIGS. 6 and 7, the sense amplifier circuit may perform a restoring operation RST of restoring a voltage of the memory cell MC.

During the restoration operation RST, the control transistor MB3 receiving the fifth control signal PTG of an active level (e.g., a high level) so that the control transistor MB3 is completely turned on.

During the restoring operation RST, the pre-charge transistor MB4 may be turned on based on the third control signal PS of an active level (e.g., a high level), connecting inverters IN1 and IN2 as a cross coupled latch. The output node OUTPUT (reflecting the data value of the node N2 sensed during the sensing operation SEN) is thus connected to the bit line through control transistor MB3 and MB1 and thus the sensed data is restored to the memory cell MC (the capacitor CS is connected the output node OUTPUT through bit line BL to be restore the corresponding charge (based on the logic level of the output node OUTPUT) in the capacitor CS, to represent data ‘1’ or data ‘0’ as appropriate).

Also, during the restoring operation RST, control transistor ML1 is turned on by virtue of control signal CSL being a logic high, and the data sensed by sense amplifier circuit 620 (the logic value represented on the output node OUTPUT) is transferred to a local IO line LIO and to local sense amplifier circuit 630. The data sensed may be further transferred to the global IO line GIO to be output (e.g., to an interface of the memory device 100 to be transmitted to a device external to the memory device 100).

In some embodiments, when data of ‘0’ is stored in the memory cell MC, the control signals PTG, LB, RB, PS, and WL may have the same timing as the control signals PTG, LB, RB, PS, and WL described with reference to FIG. 7. Accordingly, the precharge operation PC and the offset compensation operation OC may be performed as described with reference to FIG. 7.

During the charge sharing operation CS, data of ‘0’ is stored in the capacitor of the memory cell MC, and thus the voltage of the bit line BL may be reduced by charge sharing between the memory cell MC and the bit line BL.

During the charge transfer operation CT, charges (e.g., electrons) may be transferred from the bit line BL to the second node N2, and thus the voltage of the second node N2 may be decreased. In this case, since the voltage of the bit line BL is close to the ground voltage, the voltage of the second node N2 may be significantly decreased compared to FIG. 7. In addition, charges (e.g., electrons) may be transferred from the bit line BL to the second node N2, and thus the voltage of the bit line BL may be increased.

However, since the capacitance component of the second node N2 is larger than the capacitance component CBL of the bit line BL, the voltage reduction amount of the second node N2 may be lower than the voltage increase amount of the bit line BL.

During the sensing operation SEN, through the operations of the first inverter IN1 and the second inverter IN2, the voltage of the output node OUT may be reduced to the ground voltage VSS. The sense amplifier circuit may sense that data having a low level (i.e., ‘0’) is stored in the memory cell MC by virtue of sensing the logic level of the second node N2 (as described above).

Since the supply voltage difference of the second node N2 is relatively large by the charge sharing operation CS and/or the charge transfer operation CT, accurate sensing may be performed. In this case, the supply voltage difference may be amplified by a ratio of the capacitance component CBL of the bit line BL to the capacitance component CSBL of the second node N2.

During the restoration operation RST, the precharge transistor MB4 may be turned on based on the third control signal PS of an active level (e.g., a high level). In addition, charges (e.g., electrons) may be transferred from the output node OUT to the capacitor CS of the memory cell MC through the bit line transistor MB1, the first node N1, the control transistor MB3, the second node N2, and the precharge transistor MB4. Accordingly, the voltage of the output node OUT may rise, and data ‘0’ may be recovered from the memory cell MC.

FIG. 8 is an exemplary circuit diagram 800 showing the sense amplifier circuit in the memory device according to some embodiments. For convenience of explanation, differences from the contents of FIG. 6 will be mainly explained.

Referring to FIG. 8, each of the first inverter IN1 and the second inverter IN2 of the bit line sense amplifier circuit 620 may include a p-type transistor and an n-type transistor. For example, each of the first inverter IN1 and the second inverter IN2 may be a complementary MOS (CMOS) configuration of a NOT gate or inverter.

Accordingly, in some embodiments, the first inverter IN1 may include a first p-type transistor MP1 connected to an internal power supply VINTA of the bit line sense amplifier circuit 620, and a first n-type transistor MN1 connected to a ground power supply, as shown in FIG. 8. The second inverter IN2 may include a second p-type transistor MP2 connected to the internal power supply VINTA and the output node OUT of the bit line sense amplifier circuit 620, and a second n-type transistor MN2 connected to the ground power supply, as shown.

The first p-type transistor MP1, the first n-type transistor MN1, the second p-type transistor MP2, and the second n-type transistor MN2 may perform the sensing operation SEN in the first operation OP1. For example, data transferred through the bit line may be amplified.

In one example, data of high level (e.g., “1”) may be stored in the memory cell MC and may be amplified in the sensing operation SEN. Accordingly, the first n-type transistor MN1 may be turned on and the first p-type transistor MP1 may be turned off, by the voltage of the second node N2. The voltage output by the first inverter IN1 may decrease up to the ground voltage VSS through the turned-on first n-type transistor MN1. In addition, the second n-type transistor MN2 may be turned off and the second p-type transistor MP2 may be turned on, by the output of the first inverter IN1 (in response to the voltage of the second node N2, and more particularly, in response to the output of the first inverter IN1 (the inverted voltage of the second node N2), which forms the input of the second inverter IN2). The voltage of the output node OUT may increase up to the supply voltage VDD through the turned-on second p-type transistor MP2. Thus, the sense amplifier circuit may sense that data of high level (e.g., “1”) is stored in the memory cell MC. However, FIG. 8 only shows the sense amplifier circuit in the memory device according to some embodiments, but the present disclosure is not limited thereto.

Referring to FIGS. 6 and 7, the sense amplifier circuit may perform a restoring operation RST for restoring the voltage of the memory cell MC at the conclusion of the first operation OP1.

During the restoring operation RST period, the precharge transistor MB4 and the control transistor MB3 may be turned on, on the basis of the third control signal PS and the fifth control signal PTG of the active levels (e.g., a high levels). Charges (e.g., electrons) may be transferred from the capacitor CS of the memory cell MC to the output node OUT through the bit line transistor MB1, the first node N1, the control transistor MB3, the second node N2, and the precharge transistor MB4. Accordingly, the voltage of the output node OUT drops, and data “1”may be restored in the memory cell MC.

The sense amplifier circuit according to the present disclosure is a single-ended type in which each of the bit line BL and the complementary bit line BLB is connected to the first node N1, and the sense amplifier circuit of single-ended type may operate differently depending on the type of data (“0”or “1”) stored in the memory cell MC.

For example, the sense amplifier circuit of single-ended type does not need to increase the voltage of the bit line BL, if all the data stored in each of the plurality of memory cells connected to the bit line BL are “0”.

Also, when data “0” is stored in half of the memory cells connected to the bit line BL and data “1” is stored in the remaining memory cells, only the voltage of the bit line BL in which data “1” is stored may be increased. In addition, the disclosed single-ended input sense amplifier circuit may connect to only one of the bit lines BL or complementary bit lines BLB during the sensing operation and more particularly to when performing all of the operations described with respect to FIG. 7 (note that the sensing operation described with respect to FIG. 7 may alternatively have LB at low during the entire operation, including during PCG).

By contrast, a sense amplifier circuit of a differential type in which the bit line and the complementary bit line are connected to both ends of the sense amplifier circuit may amplify a voltage difference between the bit line BL and the complementary bit line BLB in the process of reading the data from the memory cell. The sense amplifier circuit of the differential type may increase the voltage of one line and decrease the voltage of the other line to amplify the voltage difference between the bit line and the complementary bit line.

Accordingly, the sense amplifier circuit of single-ended type may be driven with lower power than the sense amplifier circuit of the differential type.

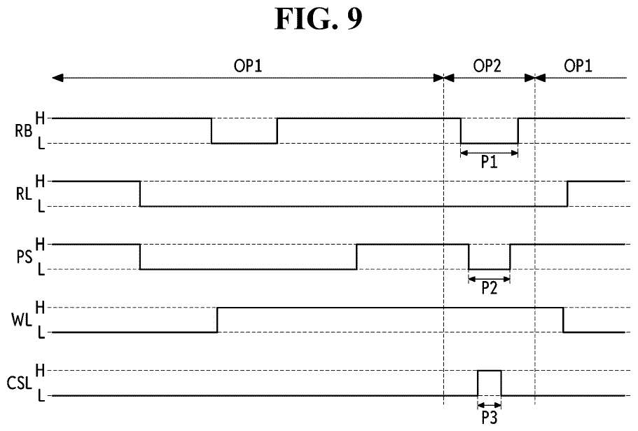

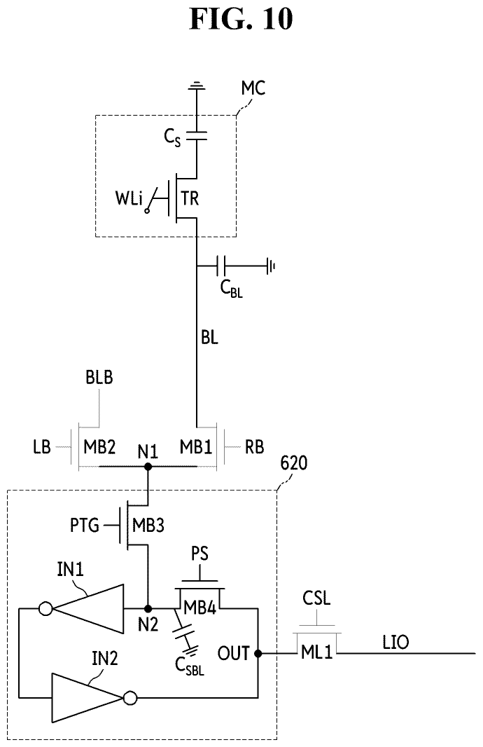

FIG. 9 is an exemplary timing diagram for explaining the second operation OP2 of the sense amplifier circuit shown in FIG. 6. As illustrated in FIG. 9 and discussed above, the second operation OP2 may occur between two repeated occurrences of the first operation OP1. FIGS. 10 to 13 are circuit diagrams of the sense amplifier circuit that performs the second operation.

Referring to FIG. 9, the second operation OP2 of the sense amplifier circuit 610 may be performed between the repeated first operations OP1. For example, the second operation OP2 of the sense amplifier circuit 610 may be performed between the restoring (e.g., final) operation RST of the first operation OP1 and the precharge (e.g., first) operation PCG of the repetition of the first operation OP1. For example, the second operation OP2 may be a read operation for reading data stored in the memory cell MC.

Referring to FIGS. 9 and 10, a first control signal RB of an inactive level (e.g., a low level) may be applied to the bit line transistor MB1. The bit line transistor MB1 may be turned off, on the basis of this first control signal RB of the inactive level. Accordingly, the electrical connection between the bit line BL and the control transistor MB3 may be disconnected. Although FIG. 9 shows that the first control signal RB applied to the bit line transistor MB1 is switched into an inactive level, in some embodiments, the second control signal LB applied to the complementary bit line transistor MB2 may be switched into an inactive level.

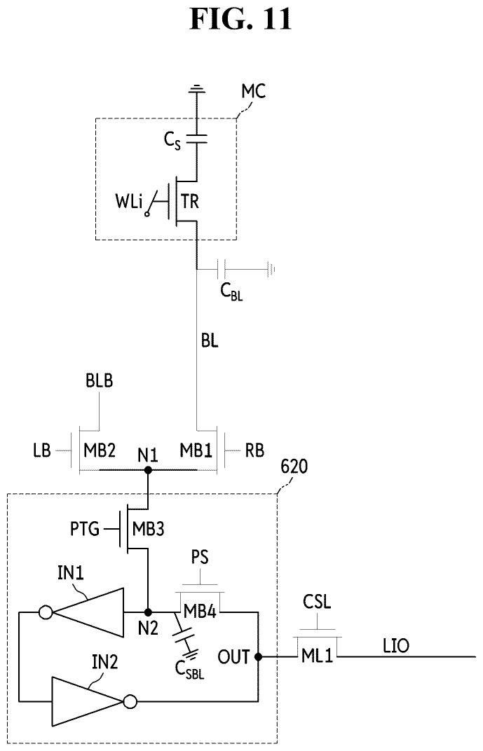

Referring to FIGS. 9 and 11, a third control signal PS of an inactive level (e.g., a low level) may be applied to the precharge transistor MB4. The precharge transistor MB4 may be turned off, on the basis of the third control signal PS of the inactive level.

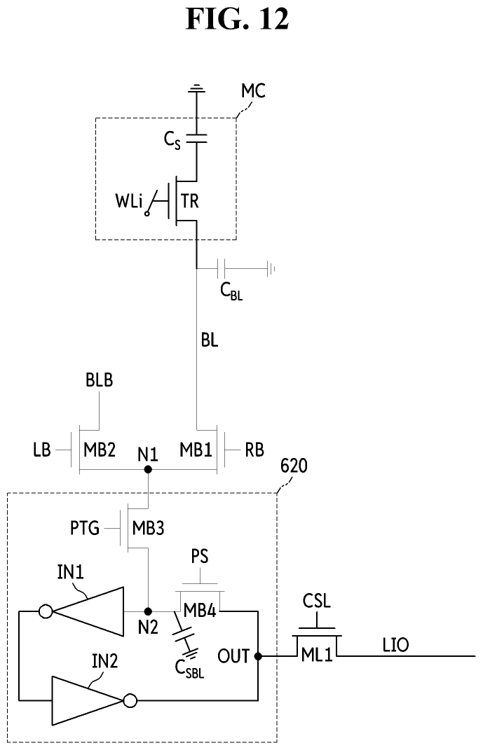

Referring to FIGS. 9 and 12, a fourth control signal CSL of an active level (e.g., a high level) may be applied to the local transistor ML1. The local transistor ML1 may be turned on, on the basis of the fourth control signal CSL of the active level. Accordingly, the local transistor ML1 may transfer the data sensed by the bit line sense amplifier circuit 620 to the local I/O line LIO.

While the local transistor ML1 is turned on, the precharge transistor MB4 and the bit line transistor MB1 may be turned off. Therefore, while the local transistor ML1 transfers the data of the output node OUT to the local I/O line LIO, the data value of the bit line sense amplifier circuit 620 may not change.

In some embodiments, the capacitance of the capacitance component CSBL of the bit line sense amplifier circuit 620 may be small. Therefore, when the local transistor ML1 is turned on, there is a high likelihood that the sensed data value of the bit line sense amplifier circuit 620 changes. By keeping the precharge transistor MB4 and the bit line transistor MB1 turned off while the local transistor ML1 is turned on, the accuracy of the operation of the bit line sense amplifier circuit 620 may be improved. In addition, the value of the data stored in the bit line BL may be prevented from changing.

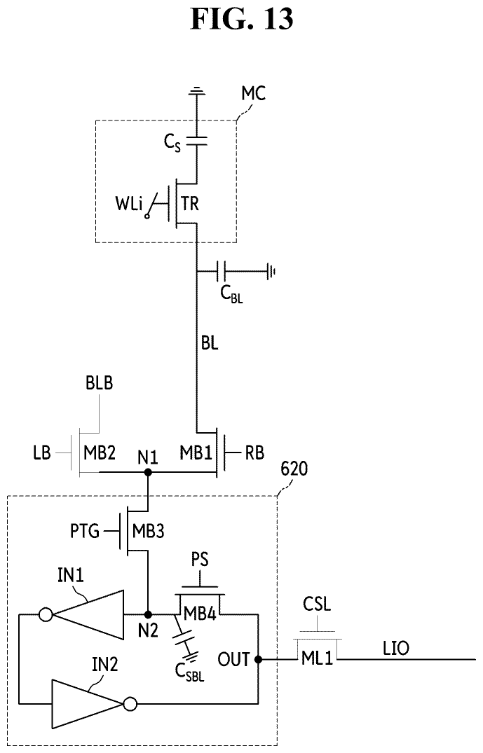

Referring to FIGS. 9 and 13, the fourth control signal CSL of the inactive level (e.g., the low level) may be applied to the local transistor ML1. The third control signal PS of the active level (e.g., the high level) may be applied to the precharge transistor MB4. The first control signal RB of the active level (e.g., the high level) may be applied to the bit line transistor MB1. Accordingly, the sense amplifier circuit 610 may perform the first operation again.

In some embodiments, the fourth control signal CSL of the inactive level, the third control signal PS of the active level, and the first control signal RB of the active level (e.g., the high level) may be applied sequentially. In another embodiment, the fourth control signal CSL of the inactive level and the third control signal PS of the active level may be applied simultaneously, and then the first control signal RB of the active level (e.g., the high level) may be applied. In yet another embodiment, the fourth control signal CSL of the inactive level, the third control signal PS of the active level, and the first control signal RB of the active level (e.g., the high level) may be applied simultaneously.

Referring again to FIG. 9, after a first time from the time point at which the first control signal RB of the inactive level is applied to the bit line transistor MB1, the first control signal RB of the active level may be applied. Switching of the first control signal RB from the active level to the inactive level and from the inactive level back to the active level during the second operation OP2 is referred to as a first pulse P1. After a second time from the time point at which the third control signal PS of the inactive level is applied to the precharge transistor MB4, the third control signal PS of the active level may be applied. Switching of the third control signal PS from the active level to the inactive level and from the inactive level back to the active level during the second operation OP2 is referred to as a second pulse P2. After a third time of the time point at which the fourth control signal CSL of the active level is applied, the fourth control signal CSL of the inactive level may be applied to the local transistor ML1. Switching of the fourth control signal CSL from the inactive level to the active level and from the active level back to the inactive level during the second operation OP2 is referred to as a third pulse P3.

In some embodiments, the first time and the second time may be greater than the third time. For example, in some embodiments, the third control signal PS may maintain the inactive level (e.g., a low level) while the fourth control signal CSL of the active level (e.g., a high level) is applied, thereby preventing the data value sensed by the disclosed bit line sense amplifier circuit 620 from spuriously changing in response to a change of the fourth control signal CSL to the active level. Accordingly, the third time (during which the fourth control signal CSL of the active level is applied), may be a subset of the second time (during which the third control signal PS maintains the inactive level). In some embodiments, the first time and the second time may be the same. In some embodiments, the first time may be greater than the second time. In some embodiments, the second time may be greater than the first time.

Thus, in some embodiments, the width (e.g., duration) of the first pulse P1 (e.g., the first time) may be greater than or equal to the width of the second pulse P2 (e.g., the second time). In some embodiments, the width of the third pulse P3 (e.g., the third time) may be smaller than the widths of the first pulse P1 and the second pulse P2. For example, the first, second, and third times, and/or the timing of these pulses, may be controlled by the control logic circuit 120, as described in the example of FIG. 1.

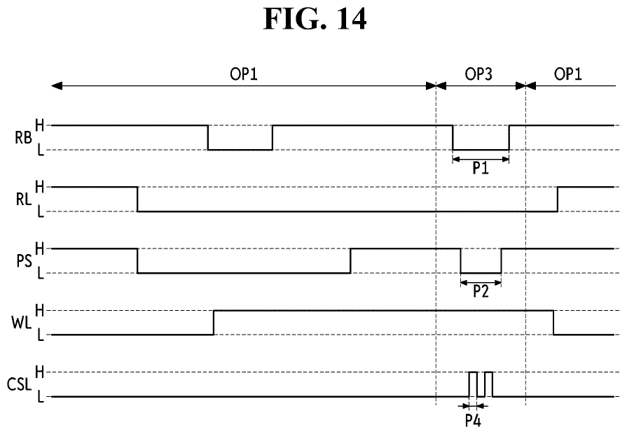

FIG. 14 is an exemplary timing diagram for explaining a third operation OP3 of the sense amplifier circuit shown in FIG. 6. For example, the third operation OP3 of the sense amplifier circuit 610 may be performed between the restoring (e.g., final) operation RST of the first operation OP1 and the precharge (e.g., first) operation PCG of the repetition of the first operation OP1. For example, the third operation OP3 may be a read operation for reading the data stored in the memory cell MC. For convenience of explanation, differences from the contents of FIGS. 9 to 13 will be mainly explained.

Referring to FIG. 14, the first control signal RB of the inactive level (e.g., the low level) may be applied to the bit line transistor MB1. The bit line transistor MB1 may be turned off, on the basis of the first control signal RB of the inactive level.

Next, the third control signal PS of the inactive level (e.g., the low level) may be applied to the precharge transistor MB4. The precharge transistor MB4 may be turned off, on the basis of the third control signal PS of the inactive level.

Next, the fourth control signal CSL of the active level (e.g., the high level) may be applied to the local transistor ML1. The local transistor ML1 may be turned on, on the basis of the fourth control signal CSL of the active level.

Next, the fourth control signal CSL of the inactive level (e.g., the low level) may be applied to the local transistor ML1. The local transistor ML1 may be turned off, on the basis of the fourth control signal CSL of the inactive level. For example, the third operation OP3 of the sense amplifier circuit 610 may apply the fourth control signal CSL of the inactive level (e.g., the low level) to the local transistor ML1 in a status in which the bit line transistor MB1 and the precharge transistor MB4 are turned off. Thus, the local transistor ML1 may be turned off, on the basis of the fourth control signal CSL of the inactive level.

Next, the fourth control signal CSL of the active level (e.g., the high level) may be applied to the local transistor ML1. The local transistor ML1 may be turned on, on the basis of the fourth control signal CSL of the active level. For example, the third operation OP3 of the sense amplifier circuit 610 may apply the fourth control signal CSL of the active level (e.g., the high level) to the local transistor ML1 in a status in which the bit line transistor MB1 and the precharge transistor MB4 are turned off. Therefore, the local transistor ML1 may be turned on, on the basis of the fourth control signal CSL of the active level. Accordingly, the operation of turning on the local transistor ML1 may be performed twice.

Finally, the fourth control signal CSL of the inactive level (e.g., the low level) is applied to the local transistor ML1, and the local transistor ML1 may be turned off. The third control signal PS of the active level (e.g., the high level) is applied to the precharge transistor MB4, and the precharge transistor MB4 may be turned on. The first control signal RB of the active level (e.g., the high level) is applied to the bit line transistor MB1, and the bit line transistor MB1 may be turned on. Accordingly, the sense amplifier circuit 610 may perform the first operation again.

As in the example of FIG. 9, in the third operation OP3, the first pulse P1 may include switching the first control signal RB from the active level to the inactive level and from the inactive level back to the active level, and the second pulse P2 may include switching the third control signal PS from the active level to the inactive level and from the inactive level back to the active level. Although FIG. 14 shows that the fourth control signal CSL repeats the fourth pulse P4, in which the fourth control signal CSL switches from the inactive level to the active level and from the active level to the inactive level, twice during the third operation OP3, the present disclosure is not limited thereto. The fourth control signal CSL may include the fourth pulse P4 twice or more times.

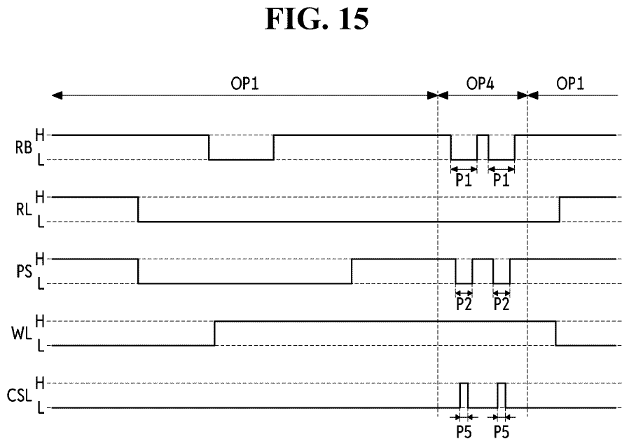

FIG. 15 is an exemplary timing diagram for explaining a fourth operation of the sense amplifier circuit shown in FIG. 6.

Referring to FIG. 15, a fourth operation OP4 of the sense amplifier circuit 610 may be performed between the repeated first operations OP1. For example, the fourth operation OP4 of the sense amplifier circuit 610 may be performed between the restoring (e.g., final) operation RST of the first operation OP1 and the precharge (e.g., first) operation PCG of the repetition of the first operation OP1. For example, the fourth operation OP4 may be a read operation for reading data stored in the memory cell MC.

For example, the fourth operation OP4 may be an operation in which the second operation OP2 is repeated multiple times between the restoring operation RST and the precharge operation PCG of the repeated first operation OP1.

Referring to FIG. 15, switching of the fourth control signal CSL from the inactive level to the active level and from the active level to the inactive level in the fourth operation OP4 is referred to as a fifth pulse P5. For example, the fourth pulse P4 of the third operation OP3 may comprise two or more pulses that cumulatively form a subset of the second pulse P2, whereas in this example, the fifth pulse P5 of the fourth operation OP4 may comprise two or more pulses that correspond respectively to two or more second pulses P2.

In some embodiments, the width (e.g., duration) of the first pulse P1 may be greater than or equal to the width of the second pulse P2. In some embodiments, the width of the fifth pulse P5 may be smaller than the widths of the first pulse P1 and the second pulse P2. For example, in some embodiments, the third control signal PS may maintain the inactive level (e.g., a low level) while the fourth control signal CSL of the active level (e.g., a high level) is applied, thereby preventing the data value sensed by bit line sense amplifier circuit 620 from spuriously changing in response to the change of the fourth control signal CSL. Accordingly, the duration of each fifth pulse P5 (during which the fourth control signal CSL of the active level is applied), may be a subset of the duration of each respective second pulse P2 (during which the third control signal PS maintains the inactive level). In some examples, the timing of these pulses may be controlled by the control logic circuit 120, as described in the example of FIG. 1.

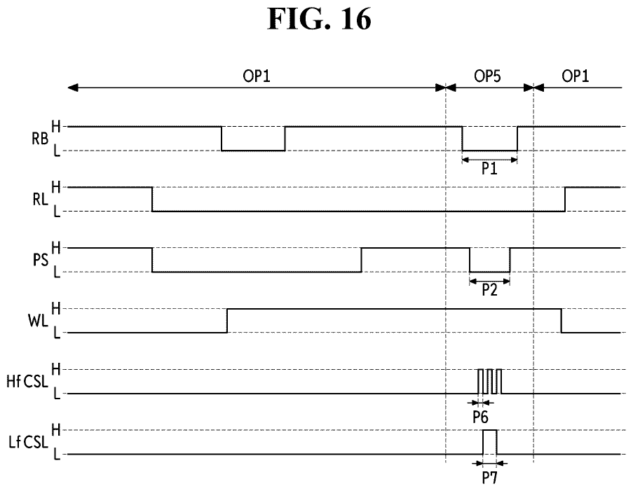

FIG. 16 is an exemplary timing diagram for explaining a fifth operation OP5 of the sense amplifier circuit shown in FIG. 6. For example, a fifth operation OP5 of the sense amplifier circuit 610 may be performed between the restoring (e.g., final) operation RST of the first operation OP1 and the precharge (e.g., first) operation PCG of the repetition of the first operation OP1. For convenience of explanation, differences from the contents of FIGS. 9 to 14 will be mainly explained.

The sense amplifier circuit 610 may operate differently depending on the frequency magnitude of the fourth control signal CSL. For example, if the frequency of the fourth control signal CSL is high (e.g., above a threshold frequency such as 50 Hz, 100 Hz, 500 Hz, 1 kHz, 100 kHz, 1 MHz, 10 MHz, or 100 MHz), the bit line transistor MB1 and the precharge transistor MB4 may not be turned off between the restoring operation RST and the precharge operation PCG of the first operation OP1. If the frequency of the fourth control signal CSL is low, the bit line transistor MB1 and the precharge transistor MB4 may be turned off between the restoring operation RST and the precharge operation PCG of the first operation OP1.

For example, referring to FIG. 16, switching of the fourth control signal Hf CSL with a high frequency from the inactive level to the active level and from the active level to the inactive level during the fifth operation OP5 is referred to as a sixth pulse P6. Switching of the fourth control signal Lf CSL with a low frequency from the inactive level to the active level and from the active level to the inactive level during the fifth operation OP5 is referred to as a seventh pulse P7.

For example, when the frequency of the fourth control signal CSL is high, the width (e.g., duration) of the sixth pulse P6 may be much smaller than the width of the first pulse P1 or the second pulse P2. For example, because the time during which the charge is shared with the local I/O line LIO is very short, the voltage of the bit line BL is less likely to fluctuate. Therefore, when the frequency of the fourth control signal CSL is high, the bit line transistor MB1 and the precharge transistor MB4 may not be turned off between the restoring operation RST and the precharge operation PCG of the first operation OP1. In some embodiments, when the frequency of the fourth control signal CSL is high, the fifth operation OP5 may be different from the second operation OP2 and the third operation OP3.

In another example, when the frequency of the fourth control signal CSL is low (e.g., below a threshold frequency such as 50 Hz, 100 Hz, 500 Hz, 1 kHz, 100 kHz, 1 MHz, 10 MHz, or 100 MHz), the width (e.g., duration) of the seventh pulse P7 may be similar to the width of the first pulse P1 or the second pulse P2. For example, the voltage of the bit line BL is likely to fluctuate while the charge is shared with the local I/O line LIO. Therefore, when the frequency of the fourth control signal CSL is low, the bit line transistor MB1 and the precharge transistor MB4 may be turned off between the restoring operation RST and the precharge operation PCG of the first operation OP1. In some embodiments, when the frequency of the fourth control signal CSL is low, the fifth operation OP5 may be the same as the second operation OP2 to the fourth operation OP4.

For example, in some embodiments, the third control signal PS may maintain the inactive level while the fourth control signal CSL of the active level is applied, thereby preventing the data value sensed by bit line sense amplifier circuit 620 from spuriously changing in response to the change of the fourth control signal CSL. Accordingly, the cumulative duration of the sixth pulse P6 and the duration of the seventh pulse P7 may respectively be subsets of the duration of the second pulse P2.

In some embodiments, the sense amplifier circuit 610 may selectively operate depending on the frequency magnitude of the fourth control signal CSL in the fifth operation OP5.

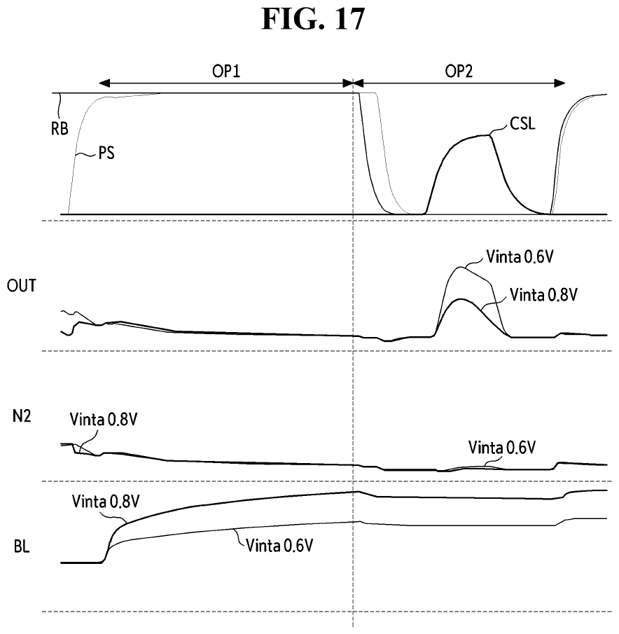

FIG. 17 is a graph showing sensing data according to an internal power supply of the sense amplifier circuit in the memory device according to some embodiments.

Referring to FIG. 17, the sense amplifier circuit 610 may perform the first operation OP1 and the second operation OP2. The graph of FIG. 16 shows data changes of the bit line BL, the second node N2, and the output node OUT according to the first operation OP1 and the second operation OP2. For example, as the internal power supply VINTA of the bit line sense amplifier circuit 620 changes, the sensing data of the output node OUT may change.

In the first operation OP1, the bit line sense amplifier circuit 620 may sense data transferred through the bit line BL. The sense amplifier circuit 610 according to the present disclosure may perform a sensing operation even when the internal power supply VINTA is a low voltage.

Also, by keeping the precharge transistor MB4 and the bit line transistor MB1 turned off while the local transistor ML1 is turned on, data change due to the operation of the local transistor ML1 may be prevented. For example, data change in the bit line sense amplifier circuit 620 and the bit line BL may be prevented. Accordingly, it is possible to improve the accuracy of the operation of the sense amplifier circuit 610. While the second operation OP2 is being performed in the sense amplifier circuit 610, there is almost no data change in the bit line BL and the second node N2.

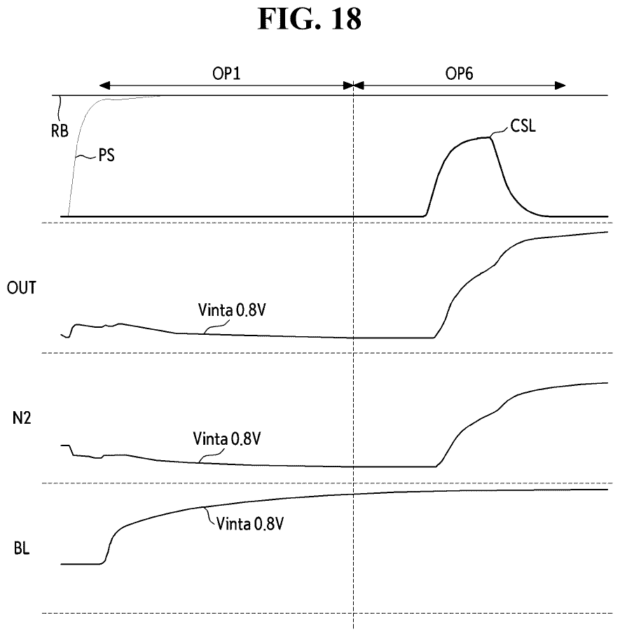

FIG. 18 is a graph showing sensing data of a sense amplifier circuit in a memory device according to some embodiments. Referring to FIG. 18, the sense amplifier circuit 610 may perform a first operation OP1 and a sixth operation OP6.

The sixth operation OP6 is an operation in which the local transistor ML1 is turned on and off, while the precharge transistor MB4 and the bit line transistor MB1 are maintained in a turned-on status. While the sense amplifier circuit 610 is performing the sixth operation OP6, the data values of the output node OUT and the second node N2 may change due to the data interference phenomenon caused by the turned-on local transistor ML1. Further, the charge amount of the capacitance component CSBL of the bit line sense amplifier circuit 620 may also change. The data value stored in the bit line BL may also change. Since the data values of the sense amplifier circuit 610 and the bit line change, the accuracy of the sense amplifier circuit 610 may decrease when the sixth operation OP6 is performed. Therefore, when the sense amplifier circuit 610 is operated according to the second to fifth operations, the accuracy of the sense amplifier circuit 610 may be improved.

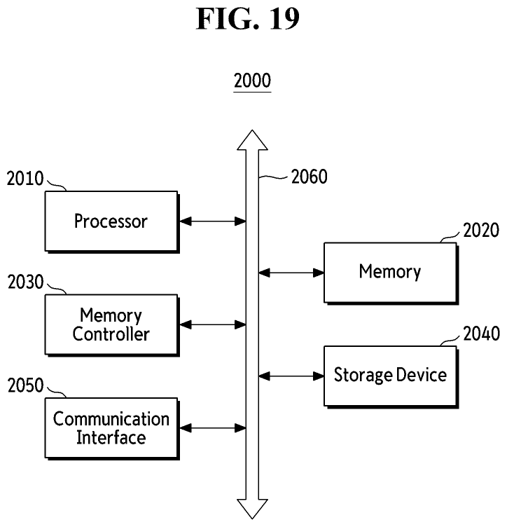

FIG. 19 is a block diagram showing a computer device including a memory device according to some embodiments.

Referring to FIG. 19, a computing device 2000 includes a processor 2010, a memory 2020, a memory controller 2030, a storage device 2040, a communication interface 2050, and a bus 2060. The computing device 2000 may further include other general-purpose components.

The processor 2010 controls the overall operation of each component of the computing device 2000. The processor 2010 may be implemented as at least one of various processing units such as a central processing unit (CPU), an application processor (AP), and a graphic processing unit (GPU).

The memory 2020 stores various types of data and instructions. The memory 2020 may be implemented as the memory device explained referring to FIGS. 1 to 16. The memory controller 2030 controls the transfer of data or instructions to and from the memory 2020. In some embodiments, the memory controller 2030 may be provided as a chip separate from the processor 2010. In some embodiments, the memory controller 2030 may be provided as an internal configuration of the processor 2010.

The storage device 2040 stores programs and data non-temporarily. In some embodiments, the storage device 2040 may be implemented as a non-volatile memory. The communication interface 2050 supports wired and wireless Internet communication of the computing device 2000. In addition, the communication interface 2050 may support various communication methods other than Internet communication. The bus 2060 provides a communication function between the components of the computing device 2000. The bus 2060 may include at least one type of bus depending on the communication protocol between the components.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

1. A memory device comprising:
a first memory cell connected to a first bit line;
a second memory cell connected to a second bit line;
a first transistor connected to the first bit line, the first transistor being configured to transfer a first data signal based on first data stored in the first memory cell to an input node of a bit line sense amplifier;
a second transistor connected to the second bit line, the second transistor being configured to transfer a second data signal based on second data stored in the second memory cell to the input node of the bit line sense amplifier;
the bit line sense amplifier connected to the input node, the bit line sense amplifier being configured to amplify a selected one of the first data signal or the second data signal provided to the input node to output a first amplified signal;
a local transistor connected to an output node of the bit line sense amplifier; and
a local sense amplifier connected to the local transistor, the local sense amplifier being configured to amplify the first amplified signal to output a second amplified signal.

2. The memory device of claim 1,
wherein the bit line sense amplifier comprises a precharge transistor which is connected to the local transistor and controls amplification of the selected one of the first data signal or the second data signal.

3. The memory device of claim 2, wherein:
the bit line sense amplifier further comprises a first inverter having a first inverter input terminal and a first inverter output terminal, and a second inverter having a second inverter input terminal and a second inverter output terminal,
the first inverter input terminal is configured to receive the first or second data signal,
the first inverter output terminal is connected to the second inverter input terminal, and
the second inverter output terminal is connected to the precharge transistor and the local transistor.

4. The memory device of claim 2,
further comprising a control logic circuit configured to output the first amplified signal to the local sense amplifier including turning on the local transistor and turning off the precharge transistor.

5. The memory device of claim 4,
wherein outputting the first amplified signal to the local sense amplifier includes the control logic circuit turning on the local transistor for a first duration and turning off the precharge transistor for a second duration, and
wherein the first time is duration than the second duration.

6. The memory device of claim 5,
wherein outputting the first amplified signal to the local sense amplifier includes the control logic circuit turning on the first transistor for a third duration, and
wherein the first duration is shorter than the third duration.

7. The memory device of claim 2,
wherein the bit line sense amplifier further comprises a control transistor which is connected to the first and second transistors, and to the first inverter input terminal.

8. The memory device of claim 2, further comprising a control logic circuit,
wherein, in response to a frequency of a first control signal for controlling the local transistor being above a threshold frequency, the local transistor is turned on and the precharge transistor is turned off by the control logic circuit, and
in response to the frequency of the first control signal for controlling the local transistor being below the threshold frequency, the local transistor is turned on independently.

9. The memory device of claim 1, further comprising a control logic circuit configured to selectively turn on the first transistor and the second transistor.

10. A memory device comprising:
a first memory cell connected to a first bit line and configured to store first data;
a first transistor including a first terminal connected to the first bit line, the first transistor being configured to transfer a first data signal representing the stored first data to a second terminal;
a bit line sense amplifier connected to the first transistor, the bit line sense amplifier being configured to amplify the first data signal to output a first amplified signal to an output node through a precharge transistor; and
a local transistor including a first local terminal connected to the output node of the bit line sense amplifier, and a second local terminal connected to a local sense amplifier, the local sense amplifier being configured to amplify the first amplified signal to output a second amplified signal; and
a control logic circuit configured to control transfer of the first amplified signal to the local sense amplifier by controlling the local transistor to be in an on state and controlling the precharge transistor to be in an off state.

11. The memory device of claim 10,
wherein the control logic circuit turns on the local transistor multiple times while maintain the precharge transistor in an off state.

12. The memory device of claim 10,
wherein the control logic circuit transfer of the first amplified signal to the local sense amplifier includes the control logic circuit maintaining the first transistor in an off state and turning on the local transistor to transfer the first amplified signal at an output of the bit line sense amplifier to the local sense amplifier.

13. The memory device of claim 12,
wherein the control logic circuit transfer of the first amplified signal to the local sense amplifier includes the control logic circuit turning off the precharge transistor and the first transistor.

14. The memory device of claim 10, further comprising:
a second memory cell connected to a second bit line and configured to store second data, and a second transistor selectively connecting the second bit line to the bit line sense amplifier.

15. The memory device of claim 14,
wherein the control logic circuit is configured to selectively turn on the first transistor and the second transistor.

16. The memory device of claim 10,
wherein, in response to a frequency of a first control signal for controlling the local transistor being above a threshold frequency, the local transistor is turned on and the precharge transistor is turned off by the control logic circuit, and
in response to the frequency of the first control signal for controlling the local transistor being below the threshold frequency, the local transistor is turned on independently.

17. The memory device of claim 10,
wherein the bit line sense amplifier further comprises a control transistor which is connected to the first transistor and the bit line sense amplifier to provide the bit line sense amplifier with the stored first data.

18. A method for driving a memory device which comprises a first memory cell connected to a first bit line and stores data, a first transistor connected to the first bit line, a bit line sense amplifier connected to the first transistor and comprising a precharge transistor, and a local transistor connected to the bit line sense amplifier and a local sense amplifier, the method comprising:
providing a first data signal based on the stored data to the bit line sense amplifier when the first transistor is turned on;
amplifying the first data signal by the bit line sense amplifier to obtain a first amplified signal;
providing the first amplified signal to an output node of the bit line sense amplifier when the precharge transistor is turned on; and
providing an output of the bit line sense amplifier to the local sense amplifier when the local transistor is has an on state and the precharge transistor has an off state to provide the first amplified signal from the output node of the bit line sense amplifier to the local sense amplifier.

19. The method for driving the memory device of claim 18,
wherein, when the first amplified signal is provided from the output node of the bit line sense amplifier to the local sense amplifier, the first transistor has an off state while the local transistor has an on state.

20. The method for driving the memory device of claim 18,
wherein, when the first amplified signal is provided from the output node of the bit line sense amplifier to the local sense amplifier, the local transistor is turned on multiple times while the precharge transistor remains in an off state.
